(19) United States
(12) Patent Application Publication
(10) Pub. No.: US 2026/0080948 A1
(43) Pub. Date: Mar. 19, 2026

(54) SEARCH FOR AN OPTIMIZED READ VOLTAGE

(71) Applicant: Micron Technology, Inc., Boise, ID (US)

(72) Inventors: Patrick Robert Khayat, San Diego, CA (US); James Fitzpatrick, Laguna Niguel, CA (US); AbdelHakim S. Alhussien, San Jose, CA (US); Sivagnanam Parthasarathy, Carlsbad, CA (US)

(21) Appl. No.: 19/402,285

(22) Filed: Nov. 26, 2025

Related U.S. Application Data
(63) Continuation of application No. 17/534,885, filed on Nov. 24, 2021, now Pat. No. 12,488,839.
Application No. 17/534,885 is a continuation of application No. 16/988,327, filed on Aug. 7, 2020, now Pat. No. 11,244,729.

(51) Int. Cl. G11C 16/26; G06F 3/06; G06F 11/10; G11C 16/04; G11C 16/34

(52) U.S. Cl. CPC G11C 16/26; G06F 3/0604; G06F 3/0659; G06F 3/0673; G06F 11/1076; G11C 16/3404; G11C 16/0483

(57) ABSTRACT

A memory device to search for a voltage optimized to read a group of memory cells. In response to a read command, the memory device measures first signal and noise characteristics of the memory cells by reading the memory cells at first test voltages. Based on the first signal and noise characteristics, the memory device may determine that the optimized read voltage is outside of a range of the first test voltages. In response, the memory device determines, based on the first signal and noise characteristics, an estimate of the optimized read voltage, and measures second signal and noise characteristics by reading at second test voltages configured around the estimate. The optimized read voltage can be computed based at least in part on the second signal and noise characteristics. The memory device retrieves data from the memory cells using the optimized read voltage.

### RELATED APPLICATIONS

The present application is a continuation application of U.S. patent application Ser. No. 17/534,885 filed Nov. 24, 2021, issued as U.S. Pat. No. 12,488,839 on Dec. 2, 2025, which is a continuation application of U.S. patent application Ser. No. 16/988,327 filed Aug. 7, 2020, issued as U.S. Pat. No. 11,244,729 on Feb. 8, 2022, the entire disclosures of which applications are hereby incorporated herein by reference.

### TECHNICAL FIELD

At least some embodiments disclosed herein relate to memory systems in general, and more particularly, but not limited to memory systems configured to search for an optimized voltage for reading data from memory cells.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The embodiments are illustrated by way of example and not limitation in the figures of the accompanying drawings in which like references indicate similar elements.

FIG. 1 illustrates an example computing system having a memory sub-system in accordance with some embodiments of the present disclosure.

FIG. 2 illustrates an integrated circuit memory device having a calibration circuit configured to measure signal and noise characteristics according to one embodiment.

FIG. 3 shows an example of measuring signal and noise characteristics to improve memory operations according to one embodiment.

FIGS. 4-6 illustrate a technique to compute an optimized read voltage from count differences according to one embodiment.

FIGS. 7-9 illustrate techniques to search for an optimized read voltage according to some embodiments.

FIG. 10 shows a method to search for an optimized read voltage for reading a group of memory cells according to one embodiment.

FIG. 11 is a block diagram of an example computer system in which embodiments of the present disclosure can operate.

### DETAILED DESCRIPTION

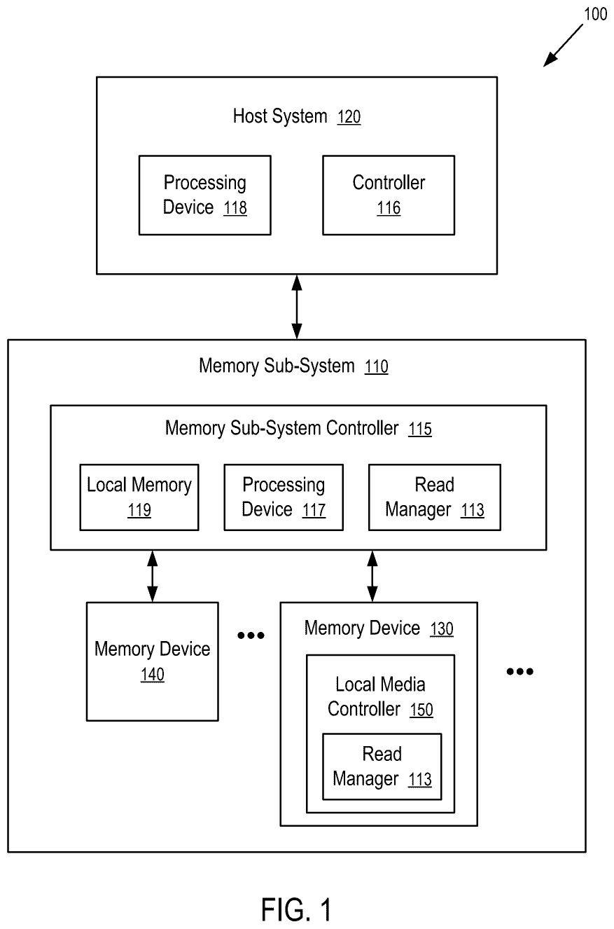

At least some aspects of the present disclosure are directed to a memory sub-system configured to search for, in an efficient way, an optimized voltage for reading a group of memory cells based on signal and noise characteristics of the group of memory cells. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

An integrated circuit memory cell (e.g., a flash memory cell) can be programmed to store data by the way of its state at a threshold voltage. For example, if the memory cell is configured/programmed in a state that allows a substantial current to pass the memory cell at the threshold voltage, the memory cell is storing a bit of one; and otherwise, the memory cell is storing a bit of zero. Further, a memory cell can store multiple bits of data by being configured/programmed differently at multiple threshold voltages. For example, the memory cell can store multiple bits of data by having a combination of states at the multiple threshold voltages; and different combinations of the states of the memory cell at the threshold voltages can be interpreted to represent different states of bits of data that is stored in the memory cell.

However, after the states of integrated circuit memory cells are configured/programmed using write operations to store data in the memory cells, the optimized threshold voltage for reading the memory cells can shift due to a number of factors, such as charge loss, read disturb, cross-temperature effect (e.g., write and read at different operating temperatures), etc., especially when a memory cell is programmed to store multiple bits of data.

Data can be encoded with redundant information to facilitate error detection and recovery. When data encoded with redundant information is stored in a memory sub-system, the memory sub-system can detect errors in raw, encoded data retrieved from the memory sub-system and/or recover the original, non-encoded data that is used to generate encoded data for storing in the memory sub-system. The recovery operation can be successful (or have a high probability of success) when the raw, encoded data retrieved from the memory sub-system contains less than a threshold amount of errors, or the bit error rate in the encoded data is lower than a threshold. For example, error detection and data recovery can be performed using techniques such as Error Correction Code (ECC), Low-Density Parity-Check (LDPC) code, etc.

When the encoded data retrieved from the memory cells of the memory sub-system has too many errors for successful decoding, the memory sub-system may retry the execution of the read command with adjusted parameters for reading the memory cells. However, it is inefficient to search for a set of parameters through multiple read retry with multiple rounds of calibration, reading, decoding failure, and retry, until the encoded data retrieved from the memory cells can be decoded into error free data. For example, blind searching for the optimized read voltages is inefficient. For example, one or more commands being injected between retry reads can lead to long latency for recovering data from errors.

Conventional calibration circuitry has been used to self-calibrate a memory region in applying read level signals to account for shift of threshold voltages of memory cells within the memory region. During the calibration, the calibration circuitry is configured to apply different test signals to the memory region to count the numbers of memory cells that output a specified data state for the test signals. Based on the counts, the calibration circuitry determines a read level offset value as a response to a calibration command.

At least some aspects of the present disclosure address the above and other deficiencies by searching for, in an efficient way, a voltage optimized to read a group of memory cells.

For example, in response to a read command, a memory device can measure signal and noise characteristics of the group of memory cells in a test voltage range.

When the voltage optimized to read a group of memory cells is determined to be within the test voltage range, the memory device calculates the optimized read voltage from the signal and noise characteristics of the group of memory cells measured in the test voltage range.

When the voltage optimized to read a group of memory cells is determined to be outside of the test voltage range, the memory device estimates a location of the next test voltage range for the search of the optimized read voltage. For example, the location of the next test voltage range can be estimated based on the signal and noise characteristics of the group of memory cells measured in the current test voltage range to improve the efficiency in searching for the optimized read voltage.

After the signal and noise characteristics of the group of memory cells are measured in the next test voltage range, the optimized read voltage is likely to be in the next test voltage range and thus can be calculated from the signal and noise characteristics of the group of memory cells measured in the next test voltage range.

Optionally, the signal and noise characteristics of the group of memory cells measured in the current test range can be stored in the memory device such that the optimized read voltage can be calculated from a combination of the signal and noise characteristics of the group of memory cells measured in both the current and next test voltage ranges.

In some instances, when the optimized read voltage is again determined to be outside of the next test voltage range, the combination of the measured signal and noise characteristics of the group of memory cells in various test voltage ranges can be used to calculate an improved estimate of the location of the optimized read voltage in the further search of the optimized read voltage.

For example, in response to a command from a controller of a memory sub-system, a memory device can automatically calibrate a voltage for reading a group of memory cells based on signal and noise characteristics measured for memory cells. The signal and noise characteristics measured for memory cells can be based on a bit count of memory cells in the group having a predetermined status when a test voltage is applied to read the memory cells. Different test voltages that are separated from one another by a predetermined voltage interval or gap can have different bit counts. The difference between bit counts of two adjacent test voltages provides the count difference for the voltage interval or gap between the adjacent test voltages. An optimized read voltage can be found at a voltage where the distribution of the count differences over voltage reaches a minimum.

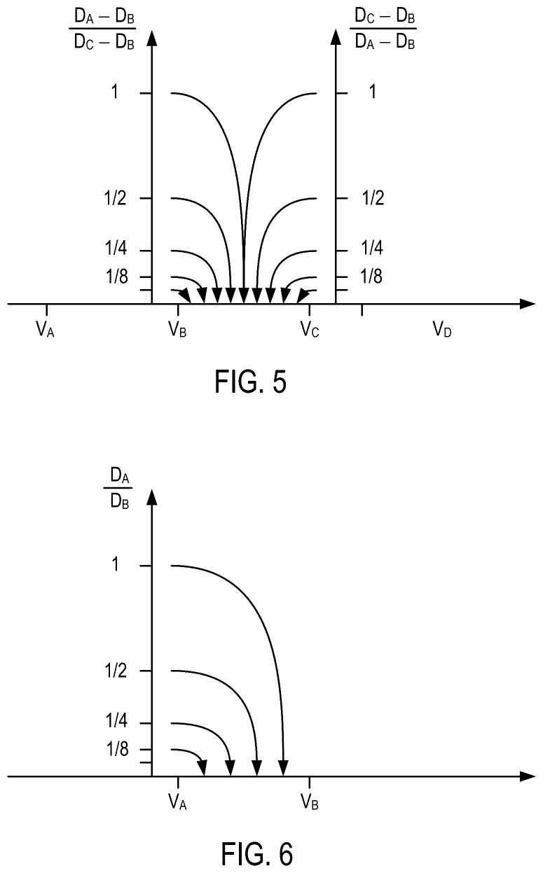

When one of the count differences is smaller than its two adjacent neighbors, a minimum can be determined to be in the voltage interval or gap of the smallest count difference. An improved location of the optimized read voltage within the gap can be computed based on a ratio of adjacent neighbors, as further discussed below in connection with FIG. 5.

When no count difference is between two higher adjacent neighbors, the optimized read voltage can be identified as in a voltage interval or gap corresponding to a count difference that is smaller than two of the next two count differences. An improved location of the optimized read voltage within the gap can be computed based on a ratio of bit counts at the test voltages of the two ends of the gap, as further discussed below in connection with FIG. 6.

When the optimized read voltage cannot be determined according to FIGS. 5 and 6, it can be concluded that the optimized read voltage is located outside of the test voltage range. In response, the distribution of the count differences in the test range can be used to estimate a location of the optimized read voltage. The calibration can then be repeated based on the estimated location of the optimize read voltage. In repeating the calibration, the test voltages are configured around the estimated location of the optimize read voltage. Thus, the estimated location of the optimize read voltage identifies a preferred direction and step size in searching for the optimized read voltage.

For example, the location of the optimized read voltage outside of a test voltage range can be estimated using an extrapolation technique based on the count differences measured within the test voltage range.

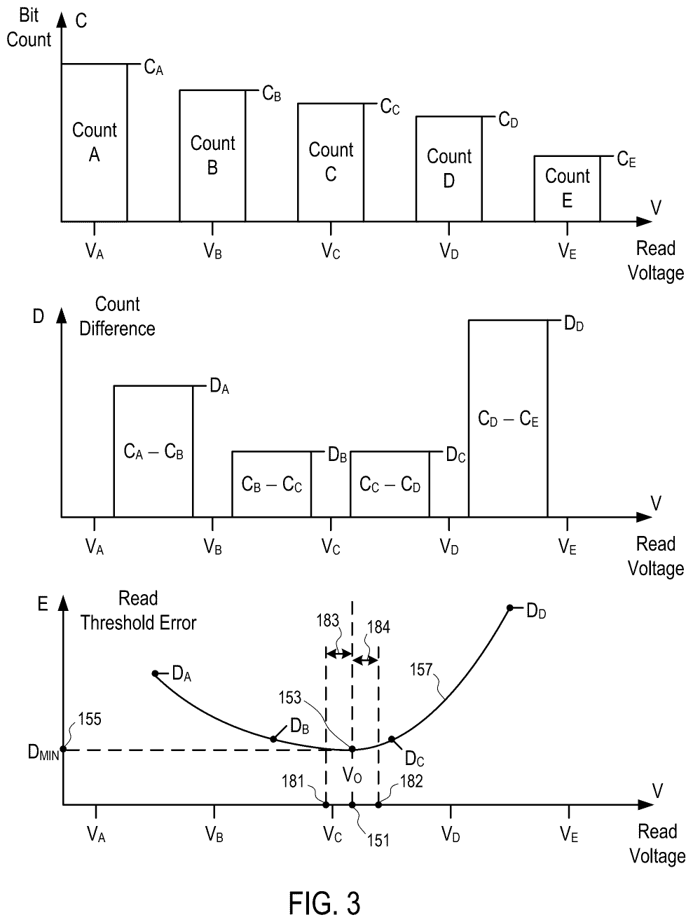

After an optimized read voltage is calculated (e.g., using techniques illustrated in FIGS. 3-6), the memory device can use the optimized read voltage to read memory cells and obtain hard bit data, and optionally boost modulating the applied read voltage(s) to adjacent voltages to further read the memory cells for soft bit data.

Preferably, the operations of reading the hard bit data and reading the soft bit data are scheduled together during the execution of the read command to minimize the time required to obtain the soft bit data and/or to avoid delay that can be caused by processing a separate read command, or by intervening operations on the memory cells.

Optionally, the signal and noise characteristics measured for memory cells are further used to evaluate the quality of the hard bit data retrieved using the calibrated read voltage(s). The evaluation can be performed at least in part concurrently with the reading of the hard bit data. Based on the evaluated quality of the hard bit data, the memory device may selectively read and/or transmit the soft bit data.

The hard bit data retrieved from a group of memory cells using the calibrated/optimized read voltage can be decoded using an error detection and data recovery technique, such as Error Correction Code (ECC), Low-Density Parity-Check (LDPC) code, etc. When the error rate in the hard bit data is high, the soft bit data, retrieved from the memory cell using read voltages with predetermined offsets from the calibrated/optimized read voltage, can be used to assist the decoding of the hard bit data. When the soft bit data is used, the error recovery capability is improved in decoding the hard bit data.

Optionally, a controller of a memory sub-system can initially send a command to a memory device to read hard bit data with calibrated read voltage; and in response to a failure in the decoding of the hard bit data, the controller can further send a command to the memory device to read the corresponding soft bit data. Such an implementation is efficient when the likelihood of a failure in decoding the hard bit data without soft bit data is lower than a threshold. However, when the likelihood is above the threshold, the overhead of sending the separate command becomes disadvantageous.

When the likelihood of using soft bit data is above a threshold, it is advantageous to transmit a single command to the memory device to cause the memory device to read the soft bit data and the hard bit data together. Further, the memory device can use the signal and noise characteristics of the memory cells to predict whether the soft bit data is likely to be used by the controller. If the likelihood of using of the soft bit data is lower than a threshold, the memory device can skip reading the soft bit data.

For example, during the calibration operation, the memory device can measure the signal and noise characteristics of the memory cells and use the measurements to calculate an optimized/calibrated read voltage for reading the memory cells. Once the optimized/calibrated read voltage is obtained, the memory device reads the memory cells to obtain the hard bit data. Subsequently, the memory device adjusts the already applied optimized/calibrated read voltage (e.g., through boosted modulation) to a predetermined offset (e.g., 50 mV) below the optimized/calibrated read voltage to retrieve a set of data, and further adjusts the currently applied voltage (e.g., through boosted modulation) to the predetermined offset above the optimized/calibrated read voltage to retrieve another set of data. The logic operation of XOR (exclusive or) of the two sets of data at the both sides of the offset (e.g., 50 mV) from the optimized/calibrated read voltage provides the indication of whether the memory cells provide the same reading at the offset locations around the optimized/calibrated read voltage. The result of the XOR operation can be used as soft bit data for decoding the hard bit data read using the optimized/calibrated read voltage. In some implementations, a larger offset (e.g., 90 mV) can be used to read another set of soft bit data that indicates whether the memory cells provide the same reading at the locations according to the larger offset (e.g., 90 mV) around the optimized/calibrated read voltage.

For example, in response to a read command from a controller of the memory sub-system, a memory device of the memory sub-system performs an operation to calibrate a read voltage of memory cells. The calibration is performed by measuring signal and noise characteristics through reading the memory cells at a number of voltage levels that are near an estimated location of the optimized read voltage. An optimized read voltage can be calculated based on statistical data of the results generated from reading the memory cells at the voltage levels. For example, the statistical data can include and/or can be based on counts measured by calibration circuitry at the voltage levels. Optionally, such signal and noise characteristics can be measured for sub-regions in parallel to reduce the total time for measuring the signal and noise characteristics. The statistical data of the results generated from reading the memory cells at the voltage levels can be used to predict whether the decoding of the hard bit data retrieved using the optimized read voltage is likely to require the use of soft bit data for successful decoding. Thus, the transmission of the soft bit data can be performed selectively based on the prediction.

For example, a predictive model can be generated through machine learning to estimate or evaluate the quality of data that can be retrieved from a set of memory cells using the calibrated/optimized read voltage(s). The predictive model can use features calculated from the measured signal and noise characteristics of the memory cells as input to generate a prediction. The reading and/or transmission of the soft bit data can be selectively skipped based on the prediction.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, a laptop computer, a network server, a mobile device, a vehicle (e.g., airplane, drone, train, automobile, or other conveyance), an Internet of Things (IoT) enabled device, am embedded computer (e.g., one included in a vehicle, industrial equipment, or a networked commercial device), or such a computing device that includes memory and a processing device.

The computing system 100 can include a host system 120 that is coupled to one or more memory sub-systems 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset (e.g., processing device 118) and a software stack executed by the processor chipset. The processor chipset can include one or more cores, one or more caches, a memory controller (e.g., controller 116) (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, a universal serial bus (USB) interface, a Fibre Channel, a Serial Attached SCSI (SAS) interface, a double data rate (DDR) memory bus interface, a Small Computer System Interface (SCSI), a dual in-line memory module (DIMM) interface (e.g., DIMM socket interface that supports Double Data Rate (DDR)), an Open NAND Flash Interface (ONFI), a Double Data Rate (DDR) interface, a Low Power Double Data Rate (LPDDR) interface, or any other interface. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the PCIe interface. The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The processing device 118 of the host system 120 can be, for example, a microprocessor, a central processing unit (CPU), a processing core of a processor, an execution unit, etc. In some instances, the controller 116 can be referred to as a memory controller, a memory management unit, and/or an initiator. In one example, the controller 116 controls the communications over a bus coupled between the host system 120 and the memory sub-system 110. In general, the controller 116 can send commands or requests to the memory sub-system 110 for desired access to memory devices 130, 140. The controller 116 can further include interface circuitry to communicate with the memory sub-system 110. The interface circuitry can convert responses received from the memory sub-system 110 into information for the host system 120.

The controller 116 of the host system 120 can communicate with the controller 115 of the memory sub-system 110 to perform operations such as reading data, writing data, or erasing data at the memory devices 130, 140 and other such operations. In some instances, the controller 116 is integrated within the same package of the processing device 118. In other instances, the controller 116 is separate from the package of the processing device 118. The controller 116 and/or the processing device 118 can include hardware such as one or more integrated circuits (ICs) and/or discrete components, a buffer memory, a cache memory, or a combination thereof. The controller 116 and/or the processing device 118 can be a microcontroller, special purpose logic circuitry (e.g., a field programmable gate array (FPGA), an application specific integrated circuit (ASIC), etc.), or another suitable processor.

The memory devices 130, 140 can include any combination of the different types of non-volatile memory components and/or volatile memory components. The volatile memory devices (e.g., memory device 140) can be, but are not limited to, random access memory (RAM), such as dynamic random access memory (DRAM) and synchronous dynamic random access memory (SDRAM).

Some examples of non-volatile memory components include a negative-and (or, NOT AND) (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, PLCs, or any combination of such. In some embodiments, a particular memory device can include an SLC portion, an MLC portion, a TLC portion, a QLC portion, and/or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory devices such as 3D cross-point type and NAND type memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations (e.g., in response to commands scheduled on a command bus by controller 116). The controller 115 can include hardware such as one or more integrated circuits (ICs) and/or discrete components, a buffer memory, or a combination thereof. The hardware can include digital circuitry with dedicated (i.e., hard-coded) logic to perform the operations described herein. The controller 115 can be a microcontroller, special purpose logic circuitry (e.g., a field programmable gate array (FPGA), an application specific integrated circuit (ASIC), etc.), or another suitable processor.

The controller 115 can include a processing device 117 (processor) configured to execute instructions stored in a local memory 119. In the illustrated example, the local memory 119 of the controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the controller 115, in another embodiment of the present disclosure, a memory sub-system 110 does not include a controller 115, and can instead rely upon external control (e.g., provided by an external host, or by a processor or controller separate from the memory sub-system).

In general, the controller 115 can receive commands or operations from the host system 120 and can convert the commands or operations into instructions or appropriate commands to achieve the desired access to the memory devices 130. The controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the controller 115 and decode the address to access the memory devices 130.

In some embodiments, the memory devices 130 include local media controllers 150 that operate in conjunction with the memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device combined with a local controller (e.g., local controller 150) for media management within the same memory device package. An example of a managed memory device is a managed NAND (MNAND) device.

The controller 115 and/or a memory device 130 can include a read manager 113 configured to search and/or calculate, based on signal and noise characteristics of a group of memory cells, a voltage optimized for reading the group of memory cells. In some embodiments, the controller 115 in the memory sub-system 110 includes at least a portion of the read manager 113. In other embodiments, or in combination, the controller 116 and/or the processing device 118 in the host system 120 includes at least a portion of the read manager 113. For example, the controller 115, the controller 116, and/or the processing device 118 can include logic circuitry implementing the read manager 113. For example, the controller 115, or the processing device 118 (processor) of the host system 120, can be configured to execute instructions stored in memory for performing the operations of the read manager 113 described herein. In some embodiments, the read manager 113 is implemented in an integrated circuit chip disposed in the memory sub-system 110. In other embodiments, the read manager 113 can be part of firmware of the memory sub-system 110, an operating system of the host system 120, a device driver, or an application, or any combination therein.

For example, the read manager 113 implemented in the controller 115 can transmit a read command or a calibration command to the memory device 130. In response to such a command, the read manager 113 implemented in the memory device 130 is configured to measure signal and noise characteristics of a group of memory cells by reading the group of memory cells at a plurality of test voltages configured near an estimated location of the optimized read voltage for the group of memory cells. The test voltages can be configured to be equally spaced by a same amount of voltage gap. A result of reading the group of memory cells at a test voltage determines a bit count of memory cells in the group that are determined to be storing or reporting a predetermined bit (e.g., 0 or 1 corresponding to memory cells being conductive or non-conductive at the test voltage) when the group is read at the test voltage. A count difference can be computed from the bit counts of each pair of adjacent test voltages. The read manager 113 compares the count difference to identify a voltage interval that contains an optimized read voltage and then estimates a location in the voltage interval for the optimized read voltage based on comparing the bit counts or count differences that are closest to the voltage interval. The estimated location can be used as the optimized read voltage to read hard bit data; and voltages having predetermined offsets from the optimized read voltage can be used to read soft bit data. In some instances, the optimized read voltage is outside of the range of the test voltages. In such situations, the read manager 113 estimates a location of the optimized read voltage for a direction and voltage step to search for the optimized read voltage. The estimation can be performed based on the measured bit counts for the current set of test voltages. The next set of test voltages can be configured around the estimated location of the optimized read voltage.

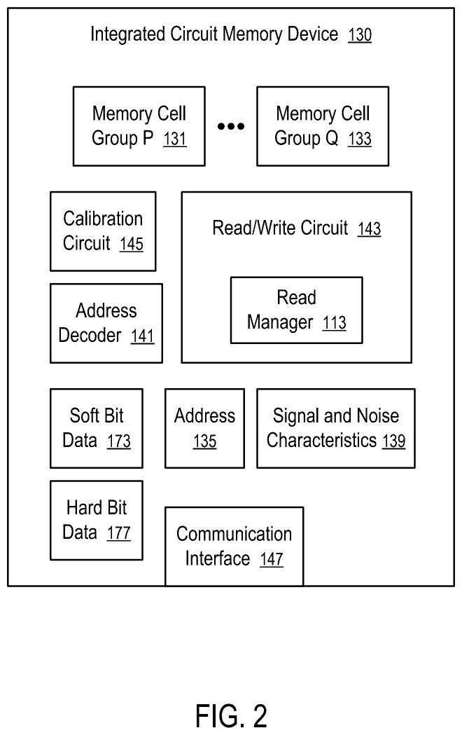

FIG. 2 illustrates an integrated circuit memory device 130 having a calibration circuit 145 configured to measure signal and noise characteristics according to one embodiment. For example, the memory devices 130 in the memory sub-system 110 of FIG. 1 can be implemented using the integrated circuit memory device 130 of FIG. 2.

The integrated circuit memory device 130 can be enclosed in a single integrated circuit package. The integrated circuit memory device 130 includes multiple groups 131, . . . , 133 of memory cells that can be formed in one or more integrated circuit dies. A typical memory cell in a group 131, . . . , 133 can be programmed to store one or more bits of data.

Some of the memory cells in the integrated circuit memory device 130 can be configured to be operated together for a particular type of operations. For example, memory cells on an integrated circuit die can be organized in planes, blocks, and pages. A plane contains multiple blocks; a block contains multiple pages; and a page can have multiple strings of memory cells. For example, an integrated circuit die can be the smallest unit that can independently execute commands or report status; identical, concurrent operations can be executed in parallel on multiple planes in an integrated circuit die; a block can be the smallest unit to perform an erase operation; and a page can be the smallest unit to perform a data program operation (to write data into memory cells). Each string has its memory cells connected to a common bitline; and the control gates of the memory cells at the same positions in the strings in a block or page are connected to a common wordline. Control signals can be applied to wordlines and bitlines to address the individual memory cells.

The integrated circuit memory device 130 has a communication interface 147 to receive a command having an address 135 from the controller 115 of a memory sub-system 110, retrieve both hard bit data 177 and soft bit data 173 from the memory address 135, and provide at least the hard bit data 177 as a response to the command. An address decoder 141 of the integrated circuit memory device 130 converts the address 135 into control signals to select a group of memory cells in the integrated circuit memory device 130; and a read/write circuit 143 of the integrated circuit memory device 130 performs operations to determine the hard bit data 177 and the soft bit data 173 of memory cells at the address 135.

The integrated circuit memory device 130 has a calibration circuit 145 configured to determine measurements of signal and noise characteristics 139 of memory cells in a group (e.g., 131, . . . , or 133). For example, the statistics of memory cells in a group or region that has a particular state at one or more test voltages can be measured to determine the signal and noise characteristics 139. Optionally, the signal and noise characteristics 139 can be provided by the memory device 130 to the controller 115 of a memory sub-system 110 via the communication interface 147.

In at least some embodiments, the calibration circuit 145 determines the optimized read voltage(s) of the group of memory cells based on the signal and noise characteristics 139. In some embodiments, the signal and noise characteristics 139 are further used in the calibration circuit 145 to determine whether the error rate in the hard bit data 177 is sufficiently high such that it is preferred to decode the hard bit data 177 in combination with the soft bit data 173 using a sophisticated decoder. When the use of the soft bit data 173 is predicted, based on the prediction/classification of the error rate in the hard bit data 177, the read manager 113 can transmit both the soft bit data 173 and the hard bit data 177 to the controller 115 of the memory sub-system 110.

For example, the calibration circuit 145 can measure the signal and noise characteristics 139 by reading different responses from the memory cells in a group (e.g., 131, . . . , 133) by varying operating parameters used to read the memory cells, such as the voltage(s) applied during an operation to read data from memory cells.

For example, the calibration circuit 145 can measure the signal and noise characteristics 139 on the fly when executing a command to read the hard bit data 177 and the soft bit data 173 from the address 135. Since the signal and noise characteristics 139 is measured as part of the operation to read the hard bit data 177 from the address 135, the signal and noise characteristics 139 can be used in the read manager 113 with reduced or no penalty on the latency in the execution of the command to read the hard bit data 177 from the address 135.

The read manager 113 of the memory device 130 is configured to use the signal and noise characteristics 139 to determine the voltages used to read memory cells identified by the address 135 for both hard bit data and soft bit data and to determine whether to transmit the soft bit data to the memory sub-system controller 115.

For example, the read manager 113 can use a predictive model, trained via machine learning, to predict the likelihood of the hard bit data 177 retrieved from a group of memory cells (e.g., group 131 or 133) failing a test of data integrity. The prediction can be made based on the signal and noise characteristics 139. Before the test is made using error-correcting code (ECC) and/or low-density parity-check (LDPC) code, or even before the hard bit data 177 is transferred to a decoder, the read manager 113 uses the signal and noise characteristics 139 to predict the result of the test. Based on the predicted result of the test, the read manager 113 determines whether to transmit the soft bit data to the memory sub-system controller 115 in a response to the command.

For example, if the hard bit data 177 is predicted to decode using a low-power decoder that uses hard bit data 177 without using the soft bit data 173, the read manager 113 can skip the transmission of the soft bit data 173 to the memory sub-system controller 115; and the read manager 113 provides the hard bit data 177, read from the memory cells using optimized read voltages calculated from the signal and noise characteristics 139, for decoding by the low-power decoder. For example, the low-power decoder can be implemented in the memory sub-system controller 115. Alternatively, the low-power decoder can be implemented in the memory device 130; and the read manager 113 can provide the result of the lower-power decoder to the memory sub-system controller 115 as the response to the received command.

For example, if the hard bit data 177 is predicted to fail in decoding in the low-power decoder but can be decoded using a high-power decoder that uses both hard bit data and soft bit data, the read manager 113 can decide to provide both the hard bit data 177 and the soft bit data 173 for decoding by the high-power decoder. For example, the high-power decoder can be implemented in the controller 115. Alternatively, the high-power decoder can be implemented in the memory device 130.

Optionally, if the hard bit data 177 is predicted to fail in decoding in decoders available in the memory sub-system 110, the read manager 113 can decide to skip transmitting the hard bit data 177 to the memory sub-system controller 115, initiate a read retry immediately, such that when the memory sub-system controller 115 requests a read retry, at least a portion of the read retry operations is performed to reduce the time for responding to the request from the memory sub-system controller 115 for a read retry. For example, during the read retry, the read manager 113 instructs the calibration circuit 145 to perform a modified calibration to obtain a new set of signal and noise characteristics 139, which can be further used to determine improved read voltages.

The data from the memory cells identified by the address (135) can include hard bit data 177 and soft bit data 173. The hard bit data 177 is retrieved using optimized read voltages. The hard bit data 177 identifies the states of the memory cells that are programmed to store data and subsequently detected in view of changes caused by factors, such as charge loss, read disturb, cross-temperature effect (e.g., write and read at different operating temperatures), etc. The soft bit data 173 is obtained by reading the memory cells using read voltages centered at each optimized read voltage with a predetermined offset from the center, optimized read voltage. The XOR of the read results at the read voltages having the offset indicates whether the memory cells provide different read results at the read voltages having the offset. The soft bit data 173 can include the XOR results. In some instances, one set of XOR results is obtained based on a smaller offset; and another set of XOR results is obtained based on a larger offset. In general, multiple sets of XOR results can be obtained for multiple offsets, where each respective offset is used to determine a lower read voltage and a higher read voltage such that both the lower and higher read voltages have the same respective offset from an optimized read voltage to determine the XOR results.

FIG. 3 shows an example of measuring signal and noise characteristics 139 to improve memory operations according to one embodiment.

In FIG. 3, the calibration circuit 145 applies different read voltages V_{A}, V_{B}, V_{C}, V_{D}, and V_{E} to read the states of memory cells in a group (e.g., 131, . . . , or 133). In general, more or less read voltages can be used to generate the signal and noise characteristics 139.

As a result of the different voltages applied during the read operation, a same memory cell in the group (e.g., 131, . . . , or 133) may show different states. Thus, the counts C_{A}, C_{B}, C_{C}, C_{D}, and C_{E} of memory cells having a predetermined state at different read voltages V_{A}, V_{B}, V_{C}, V_{D}, and V_{E} can be different in general. The predetermined state can be a state of having substantial current passing through the memory cells, or a state of having no substantial current passing through the memory cells. The counts C_{A}, C_{B}, C_{C}, C_{D}, and C_{E} can be referred to as bit counts.

The calibration circuit 145 can measure the bit counts by applying the read voltages V_{A}, V_{B}, V_{C}, V_{D}, and V_{E} one at a time on the group (e.g., 131, . . . , or 133) of memory cells.

Alternatively, the group (e.g., 131, . . . , or 133) of memory cells can be configured as multiple subgroups; and the calibration circuit 145 can measure the bit counts of the subgroups in parallel by applying the read voltages V_{A}, V_{B}, V_{C}, V_{D}, and V_{E}. The bit counts of the subgroups are considered as representative of the bit counts in the entire group (e.g., 131, . . . , or 133). Thus, the time duration of obtaining the counts C_{A}, C_{B}, C_{C}, C_{D}, and C_{E} can be reduced.

In some embodiments, the bit counts C_{A}, C_{B}, C_{C}, C_{D}, and C_{E} are measured during the execution of a command to read the data from the address 135 that is mapped to one or more memory cells in the group (e.g., 131, . . . , or 133). Thus, the controller 115 does not need to send a separate command to request for the signal and noise characteristics 139 that is based on the bit counts C_{A}, C_{B}, C_{C}, C_{D}, and C_{E}.

The differences between the bit counts of the adjacent voltages are indicative of the errors in reading the states of the memory cells in the group (e.g., 133, . . . , or 133).

For example, the count difference D_{A} is calculated from C_{A}−C_{B}, which is an indication of read threshold error introduced by changing the read voltage from V_{A} to V_{B}.

Similarly, D_{B}=C_{B}−C_{C}; D_{C}=C_{C}−C_{D}; and D_{D}=C_{D}−C_{E}.

The curve 157, obtained based on the count differences D_{A}, D_{B}, D_{C}, and D_{D}, represents the prediction of read threshold error E as a function of the read voltage.

From the curve 157 (and/or the count differences), the optimized read voltage V_{O} can be calculated as the point 153 that provides the lowest read threshold error D_{MIN} on the curve 157.

In one embodiment, the calibration circuit 145 computes the optimized read voltage V_{O} and causes the read/write circuit 143 to read the data from the address 135 using the optimized read voltage V_{O}.

Alternatively, the calibration circuit 145 can provide, via the communication interface 147 to the controller 115 of the memory sub-system 110, the count differences D_{A}, D_{B}, D_{C}, and D_{D} and/or the optimized read voltage V_{O} calculated by the calibration circuit 145.

FIG. 3 illustrates an example of generating a set of statistical data (e.g., bit counts and/or count differences) for reading at an optimized read voltage V_{O}. In general, a group of memory cells can be configured to store more than one bit in a memory cell; and multiple read voltages are used to read the data stored in the memory cells. A set of statistical data can be similarly measured for each of the read voltages to identify the corresponding optimized read voltage, where the test voltages in each set of statistical data are configured in the vicinity of the expected location of the corresponding optimized read voltage. Thus, the signal and noise characteristics 139 measured for a memory cell group (e.g., 131 or 133) can include multiple sets of statistical data measured for the multiple threshold voltages respectively.

For example, the controller 115 can instruct the memory device 130 to perform a read operation by providing an address 135 and at least one read control parameter. For example, the read control parameter can be a suggested read voltage.

The memory device 130 can perform the read operation by determining the states of memory cells at the address 135 at a read voltage and provide the data according to the determined states.

During the read operation, the calibration circuit 145 of the memory device 130 generates the signal and noise characteristics 139. The data and the signal and noise characteristics 139 are provided from the memory device 130 to the controller 115 as a response. Alternatively, the processing of the signal and noise characteristics 139 can be performed at least in part using logic circuitry configured in the memory device 130. For example, the processing of the signal and noise characteristics 139 can be implemented partially or entirely using the processing logic configured in the memory device 130. For example, the processing logic can be implemented using Complementary metal-oxide-semiconductor (CMOS) circuitry formed under the array of memory cells on an integrated circuit die of the memory device 130. For example, the processing logic can be formed, within the integrated circuit package of the memory device 130, on a separate integrated circuit die that is connected to the integrated circuit die having the memory cells using Through-Silicon Vias (TSVs) and/or other connection techniques.

The signal and noise characteristics 139 can be determined based at least in part on the read control parameter. For example, when the read control parameter is a suggested read voltage for reading the memory cells at the address 135, the calibration circuit 145 can compute the read voltages V_{A}, V_{B}, V_{C}, V_{D}, and V_{E} that are in the vicinity of the suggested read voltage.

The signal and noise characteristics 139 can include the bit counts C_{A}, C_{B}, C_{C}, C_{D}, and C_{E}. Alternatively, or in combination, the signal and noise characteristics 139 can include the count differences D_{A}, D_{B}, D_{C}, and D_{D}.

Optionally, the calibration circuit 145 uses one method to compute an optimized read voltage V_{O} from the count differences D_{A}, D_{B}, D_{C}, and D_{D}; and the controller 115 uses another different method to compute the optimized read voltage V_{O} from the signal and noise characteristics 139 and optionally other data that is not available to the calibration circuit 145.

When the calibration circuit 145 can compute the optimized read voltage V_{O} from the count differences D_{A}, D_{B}, D_{C}, and D_{D} generated during the read operation, the signal and noise characteristics can optionally include the optimized read voltage V_{O}.

Further, the memory device 130 can use the optimized read voltage V_{O} in determining the hard bit data 177 in the data from the memory cells at the address 135. The soft bit data in the data can be obtained by reading the memory cells with read voltages that are a predetermined offset away from the optimized read voltage V_{O}. Alternatively, the memory device 130 uses the controller-specified read voltage provided in the read control parameter in reading the data.

The controller 115 can be configured with more processing power than the calibration circuit 145 of the integrated circuit memory device 130. Further, the controller 115 can have other signal and noise characteristics applicable to the memory cells in the group (e.g., 133, . . . , or 133). Thus, in general, the controller 115 can compute a more accurate estimation of the optimized read voltage V_{O} (e.g., for a subsequent read operation, or for a retry of the read operation).

In general, it is not necessary for the calibration circuit 145 to provide the signal and noise characteristics 139 in the form of a distribution of bit counts over a set of read voltages, or in the form of a distribution of count differences over a set of read voltages. For example, the calibration circuit 145 can provide the optimized read voltage V_{O} calculated by the calibration circuit 145, as signal and noise characteristics 139.

The calibration circuit 145 can be configured to generate the signal and noise characteristics 139 (e.g., the bit counts, or bit count differences) as a byproduct of a read operation. The generation of the signal and noise characteristics 139 can be implemented in the integrated circuit memory device 130 with little or no impact on the latency of the read operation in comparison with a typical read without the generation of the signal and noise characteristics 139. Thus, the calibration circuit 145 can determine signal and noise characteristics 139 efficiently as a byproduct of performing a read operation according to a command from the controller 115 of the memory sub-system 110.

In general, the calculation of the optimized read voltage V_{O} can be performed within the memory device 130, or by a controller 115 of the memory sub-system 110 that receives the signal and noise characteristics 139 as part of enriched status response from the memory device 130.

The hard bit data 177 can be obtained by applying the optimized read voltage V_{O} on the group of memory cells and determining the state of the memory cells while the memory cells are subjected to the optimized read voltages V_{O}.

The soft bit data 173 can be obtained by applying the read voltages 181 and 182 that are offset from the optimized read voltage V_{O} with a predetermined amount. For example, the read voltage 181 is at the offset 183 of the predetermined amount lower from the optimized read voltage V_{O}; and the read voltage 182 is at the offset 184 of the same predetermined amount higher from the optimized read voltage V_{O}. A memory cell subjected to the read voltage 181 can have a state that is different from the memory cell subjected to the read voltage 182. The soft bit data 173 can include or indicate the XOR result of the data read from the memory cell using the read voltages 181 and 182. The XOR result shows whether the memory cell subjected to the read voltage 181 has the same state as being to the read voltage 182.

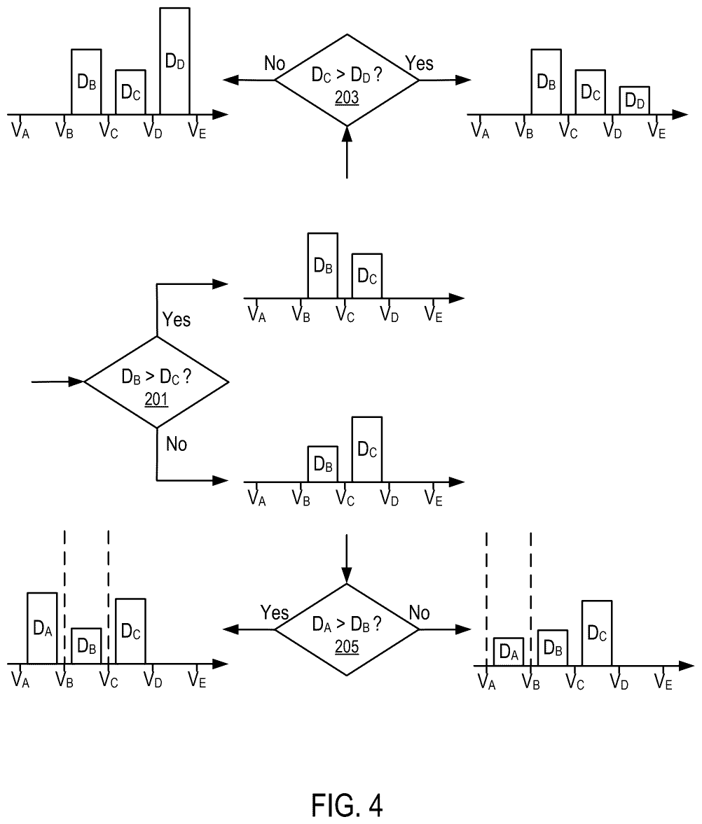

FIGS. 4-6 illustrate a technique to compute an optimized read voltage from count differences according to one embodiment. The technique of FIGS. 4-6 simplifies the computation for calculating the optimized read voltage V_{O} such that the computation can be implemented using reduced computing power and/or circuitry.

The computation illustrated in FIGS. 4-6 can be performed based on the bit counts and count differences illustrated in FIG. 3 for test voltages V_{A}, V_{B}, V_{C}, V_{D}, and V_{E}.

In FIG. 4, an operation 201 is performed to compare the two center count differences D_{B} and D_{C}.

If D_{B} is greater than D_{C}, it can be assumed that a minimal can be found on the higher half of the test voltage region between V_{C} to V_{E}. Thus, operation 203 is performed to compare the lower one D_{C} of the two center bit count differences with its other neighbor D_{D}.

If D_{C} is no greater than its other neighbor D_{D}, D_{C} is no greater than its neighbors D_{B} and D_{D}. Thus, it can be inferred that a minimal can be found between the test voltages V_{C} and V_{D}. Based on a ratio between the differences of D_{C} from its neighbors D_{B} and D_{D}, an estimate of the location of the optimized read voltage V_{O} can be determined using a technique similar to that illustrated in FIG. 5.

If D_{C} is greater than its other neighbor D_{D}, it can be assumed that a minimal can be in the highest test voltage interval between V_{D} and V_{E}. Thus, an estimate of the location of the optimized read voltage V_{O} can be determined using a technique similar to that illustrated in FIG. 6, based on a ratio of count differences D_{D} and D_{C} that are closest to the test voltages V_{D} and V_{E}.

Similarly, if D_{B} is no greater than D_{C}, it can be assumed that a minimal can be found on the lower half of the test voltage region between V_{A} to V_{C}. Thus, operation 205 is performed to compare the lower one D_{B} of the two center bit count differences with its other neighbor D_{A}.

If D_{B} is less than its other neighbor D_{A}, D_{B} is no greater than its neighbors D_{A} and D_{C}. Thus, it can be inferred that a minimal can be found between the test voltages V_{B} and V_{C}. Based on a ratio between the differences of D_{B} from its neighbors D_{A} and D_{C}, an estimate of the location of the optimized read voltage V_{O} can be determined using a technique illustrated in FIG. 5.

If D_{B} is no less than its other neighbor D_{A}, it can be assumed that a minimal can be in the lowest test voltage interval between V_{A} and V_{B}. Thus, an estimate of the location of the optimized read voltage V_{O} can be determined using a technique illustrated in FIG. 6, based on a ratio of the count differences D_{A} and D_{B} that are closest to the test voltages V_{A} and V_{B}.

FIG. 5 illustrates a technique to estimate the location of the optimized read voltage V_{O} when a center count difference D_{B} is no greater than its neighbors D_{A} and D_{C}.

Since the count difference D_{B} is the difference of bit counts C_{B} and C_{C} at test voltages V_{B} and V_{C}, the location of the optimized read voltage V_{O} is estimated to be within the voltage interval or gap between V_{B} and V_{C}.

When the increases from the center count difference D_{B} to its neighbors D_{A} and D_{C} are substantially equal to each other, the optimized read voltage V_{O} is estimated at the midpoint between V_{B} and V_{C}.

The ratio between the increases from the center count difference D_{B} to its neighbors D_{A} and D_{C} can be mapped in a logarithmic scale to a line scale of division between the test voltages V_{B} and V_{C}.

For example, the ratio (D_{A}−D_{B})/(D_{C}−D_{B}) of 1 is mapped to a location of the optimized read voltage at the midpoint between the test voltages V_{B} and V_{C}.

The ratio (D_{A}−D_{B})/(D_{C}−D_{B}) of ½ is mapped to a location of the optimized read voltage at the midpoint between the test voltages V_{B} and V_{C} with an offset of a fixed increment towards V_{B}. For example, the increment can be one tenth of the voltage gap between V_{B} and V_{C}.

Similarly, the ratio (D_{A}−D_{B})/(D_{C}−D_{B}) of ¼, ⅛, or 1/16 is mapped to a location of the optimized read voltage at the midpoint between the test voltages V_{B} and V_{C} with an offset of two, three, or four increments towards V_{B}. A ratio (D_{A}−D_{B})/(D_{C}−D_{B}) smaller than 1/16 can be mapped to a location of the optimized read voltage at V_{B}.

Similarly, the ratio (D_{C}−D_{B})/(D_{A}−D_{B}) of ½, ¼, ⅛, or 1/16 is mapped to a location of the optimized read voltage at the midpoint between the test voltages V_{B} and V_{C} with an offset of one, two, three, or four increments towards V_{C}. A ratio (D_{C}−D_{B})/(D_{A}−D_{B}) smaller than 1/16 can be mapped to a location of the optimized read voltage at V_{C}.

The technique of FIG. 5 can be implemented via setting a coarse estimation of the optimized read voltage at V_{B} (or V_{C}) and adjusting the coarse estimation through applying the increment according to comparison of the increase (D_{A}−D_{B}) of the count difference D_{B} to the count difference D_{A} with fractions or multiples of the increase (D_{C}−D_{B}) of the count difference D_{B} to the count difference D_{C}. The fractions or multiples of the increase (D_{C}−D_{B}) in a logarithmic scale can be computed through iterative division or multiplication by two, which can be implemented efficiently through bit-wise left shift or right shift operations.

For example, the initial estimate of the optimized voltage V_{O} can be set at the test voltage V_{B}. The increase (D_{A}−D_{B}) can be compared with (D_{C}−D_{B})/16, which can be computed through shifting the bits of (D_{C}−D_{B}). If (D_{A}−D_{B}) is greater than (D_{C}−D_{B})/16, the increment of one tenth of the gap between V_{B} and V_{C} can be added to the estimate of the optimized voltage V_{O}. Subsequently, (D_{A}−D_{B}) is compared to (D_{C}−D_{B})/8, which can be calculated by shifting the bits of (D_{C}−D_{B})/16. If (D_{A}−D_{B}) is greater than (D_{C}−D_{B})/8, the same increment of one tenth of the gap between V_{B} and V_{C} is further added to the estimation of the optimized voltage V_{O}. Similarly, (D_{A}−D_{B}) is compared to (D_{C}−D_{B})/4, (D_{C}−D_{B})/2, (D_{C}−D_{B}), (D_{C}−D_{B})*2, (D_{C}−D_{B})*4, (D_{C}−D_{B})*8, and (D_{C}−D_{B})*16 one after another. If (D_{A}−D_{B}) is greater than any of these scaled versions of (D_{C}−D_{B}) in a comparison, the same increment is added to the estimate. After the series of comparisons, the resulting estimate can be used as the optimized voltage V_{O}.

FIG. 6 illustrates a technique to estimate the location of the optimized read voltage V_{O} when a side count difference D_{A} is smaller than its next two count differences D_{B} and D_{C}, but one of its neighbors has not been measured (e.g., a count difference between the test voltage V_{A} and a further test voltage that is lower than V_{A}).

Since the count difference D_{A} is the lowest among count differences D_{A}, D_{B} and D_{C}, the optimized voltage V_{O} is estimated to be in the test voltage interval gap corresponding to the count difference D_{A}. Since the count difference D_{A} is the difference of bit counts C_{A} and C_{B} at test voltages V_{A} and V_{B}, the location of the optimized read voltage V_{O} is estimated to be within the voltage interval or gap between V_{A} and V_{B}.

In FIG. 6, the location of the optimized read voltage V_{O} within the voltage interval or gap between V_{A} and V_{B} is based on a ratio of the count differences D_{A} and D_{B}. The ratio D_{A}/D_{B} in a logarithmic scale is mapped to the linear distribution of the optimized read voltage V_{O} between V_{A} and V_{B}.

For example, the voltage interval or gap between V_{A} and V_{B} can be divided into five equal increments. The initial estimate of the optimized voltage V_{O} can be set at the test voltage V_{B}. The count difference D_{A} can be compared to scaled versions of the count difference D_{B} sequentially, such as D_{B}, D_{B}/2, and D_{B}/4. If the count difference D_{A} is smaller than any of the scaled versions of the count difference D_{B} in a comparison, the estimate is reduced by the increment for moving towards the test voltage V_{A}.

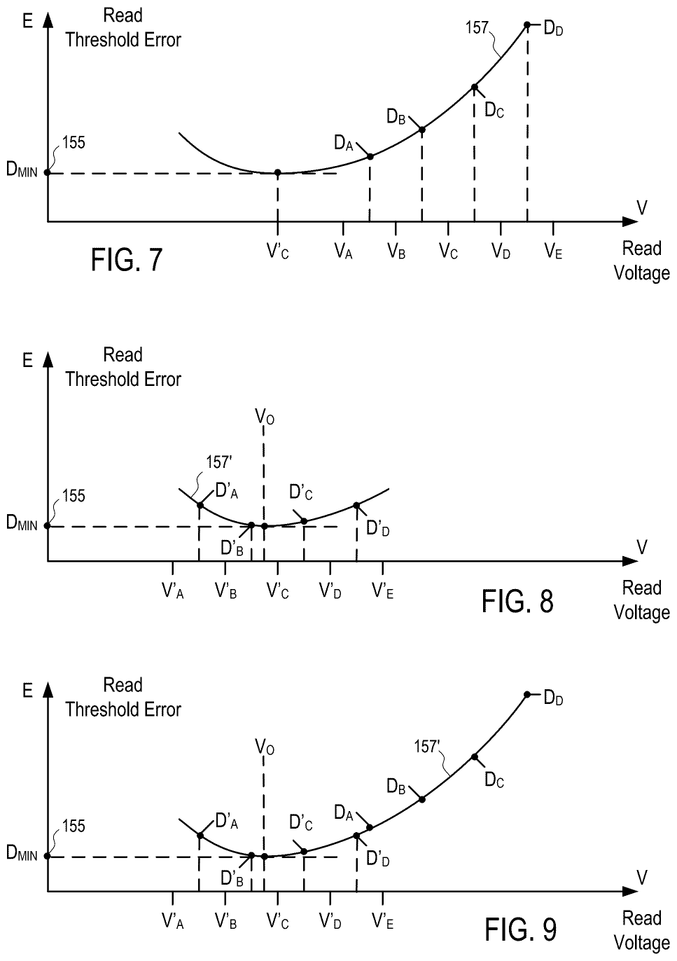

FIGS. 7-9 illustrate techniques to search for an optimized read voltage according to some embodiments.

FIG. 7 illustrates a scenario where a distribution 157 of the count differences D_{A}, D_{B}, D_{C}, and D_{D} measured in the test voltage range V_{A} to V_{E} indicates that the optimized read voltage is located outside of the test voltage range V_{A} to V_{E}.

In some implementations, the calibration circuit 145 of the memory device 130 is configured to measure the bit counts by reading at different voltages applied via boost modulation. The technique of boost modulation can limit the range of test voltages that can be applied during a single calibration operation. Thus, when the optimized read voltage is outside of the test voltage range V_{A} to V_{E}, the memory device 130 may not be able to read outside of the test voltage range V_{A} to V_{E} without restarting the calibration/read operation.

In FIG. 7, the distribution 157 of the count differences D_{A}, D_{B}, D_{C}, and D_{D} measured in the test voltage range V_{A} to V_{E} can be used by a read manager 113 of the memory device 130 to calculate a likely location V′_{C} where the distribution 157 is determined to reach a minimum 155. For example, an extrapolation technique can be used to estimate the location V′_{C} from the count differences D_{A} to D_{D}.

The location V′_{C} identifies a direction for searching the optimized read voltage (e.g., whether in a direction of voltages lower than V_{A}, or in a direction of voltages higher than V_{E}.)

Further, the location V′_{C} identifies the size of a step to search for the optimized read voltage. The size of the search step determines the gap between the previous estimate V_{C} of the location of the optimized read voltage and the current, improved estimate V′_{C} of the location of the optimized read voltage.

Based on the current, improved estimate V′_{C} of the optimized read voltage, the read manager 113 of the memory device 130 can restart the calibration/read operation, as illustrated in FIG. 8.

FIG. 8 illustrates the distribution 157′ of the count differences D′_{A}, D′_{B}, D′_{C}, and D′_{D} measured in the test voltage range V′_{A} to V′_{E} centered at the improved estimate V′_{C} of the optimized read voltage.

Since the distribution 157′ indicates that the optimized read voltage is within the test voltage range V′_{A} to V′_{E}, the techniques of FIGS. 4-6 can be used to calculate the optimized read voltage V_{O} efficiently.

Alternatively, the optimized read voltage V_{O} can be computed more accurately using the combination of both sets of count differences D_{A} to D_{D} and D′_{A} to D′_{D}, as illustrated in FIG. 9. In some instance, the optimized read voltage V_{O} can be best calculated using a portion of the count differences D_{A} to D_{D} and a portion of the count differences D′_{A} to D′_{D}. For example, the optimized read voltage V_{O} can be calculated from D′_{C}, D′_{D} and D_{A} when the optimized read voltage V_{O} is between V′_{C} and V_{B}. For example, the optimized read voltage V_{O} can be calculated from D′_{D}, D_{A} and D_{B} when the optimized read voltage V_{O} is between V′_{D} and V_{C}.

The size of the search step can be characterized by the gap between V′_{C} and V_{C} (or V′_{C} and V_{A}). Optionally, the size of the search step can be estimated as a multiple of the voltage gap or interval G between adjacent test voltages (e.g., G=V_{B}−V_{A}=V_{C}−V_{B}=V_{D}−V_{C}=V_{E}−V_{D}=V′_{B}−V′_{A}=V′_{C}−V′_{B}=V′_{D}−V′_{C}=V′_{E}−V′_{D}). Such an arrangement can simplify the computation of the optimized read voltage V_{O} from the combination of the count differences D_{A} to D_{D} and D′_{A} to D′_{D}.

In some instances, the test voltage ranges V′_{A} to V′_{E} and V_{A} to V_{E} can partially overlap with each other. When the size of the search step is a multiple of the voltage gap G (e.g., G=V_{B}−V_{A}), some of the test voltages V′_{A} to V′_{E} can be the same as some of the test voltages V_{A} to V_{E}. Thus, boost modulation operations to read bit counts at some of the test voltages can be skipped, or be repeated for improved accuracy when portions are measured in parallel; and the corresponding bit count(s) measured in the previous calibration operation can be used, or be averaged with the current measurements for improve accuracy.

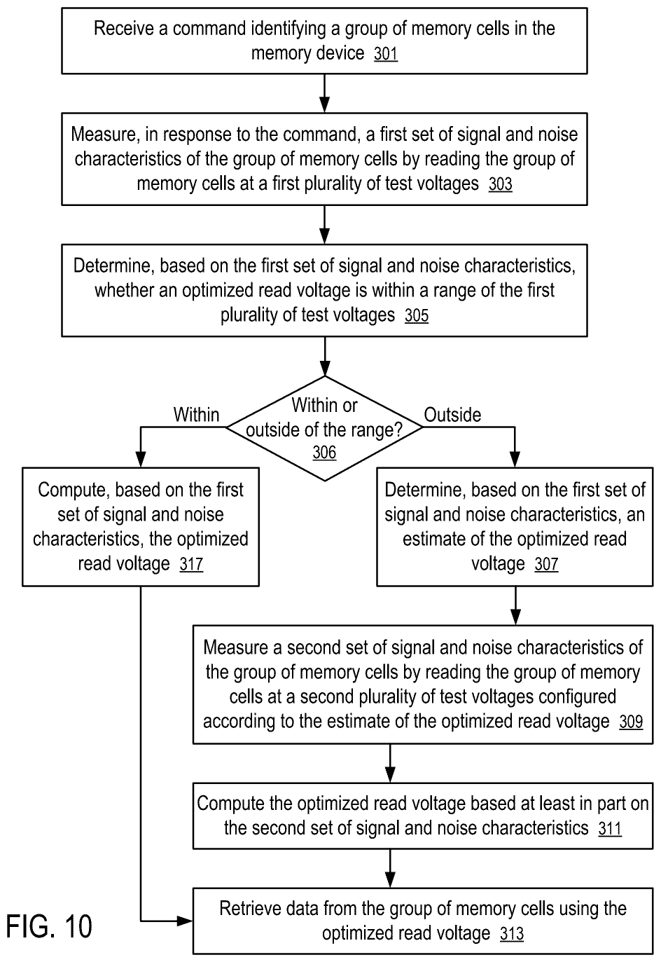

FIG. 10 shows a method to search for an optimized read voltage for reading a group of memory cells according to one embodiment. The method of FIG. 10 can be performed by processing logic that can include hardware (e.g., processing device, circuitry, dedicated logic, programmable logic, microcode, hardware of a device, integrated circuit, etc.), software/firmware (e.g., instructions run or executed on a processing device), or a combination thereof. In some embodiments, the method of FIG. 10 is performed at least in part by the controller 115 of FIG. 1, or processing logic in the memory device 130 of FIG. 2. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

For example, the method of FIG. 10 can be implemented in a computing system of FIG. 1 with a memory device of FIG. 2 and signal noise characteristics illustrated in FIG. 3 with some of the operations illustrated in FIGS. 4-9.

At block 301, a memory device 130 receives a command identifying a group of memory cells (e.g., group 131 or 133) in the memory device 130.

At block 303, the memory device 130 measures, in response to the command, a first set of signal and noise characteristics of the group of memory cells (e.g., group 131 or 133) by reading the group of memory cells (e.g., group 131 or 133) at a first plurality of test voltages (e.g., V_{A} to V_{E}).

For example, the memory device 130 can read the group of memory cells at the first plurality of test voltages V_{A} to V_{E} by initially ramping up to a test voltage (e.g., V_{C}) in the first plurality of test voltages V_{A} to V_{E} to read the group of memory cells and then boost modulating from the applied test voltage (e.g., V_{C}) to other test voltages (e.g., V_{A}, V_{B}, V_{D}, V_{E}) in the first plurality of test voltages V_{A} to V_{E} to further read the group of memory cells (e.g., group 131 or 133). In some implementations, different sub-groups of memory cells in the group (e.g., 131 or 133) are boost modulated to different test voltages (e.g., V_{A}, V_{B}, V_{D}, V_{E} respectively) for measuring in parallel. The measurements of a sub-group can be scaled to determine the measurement of the group. The memory device 130 can read the group of memory cells (e.g., group 131 or 133) at a voltage within the range of the first plurality of test voltages V_{A} to V_{E} via boost modulation but may not be able to boost modulate to a voltage that is outside of the range V_{A} to V_{E} without restarting the read/calibration operation.

At block 305, the memory device 130 determines, based on the first set of signal and noise characteristics, whether an optimized read voltage V_{O} is within a range of the first plurality of test voltages (e.g., V_{A} to V_{E}).

If, at block 306, the memory device 130 determines that the optimized read voltage V_{O} is outside of the range (e.g., V_{A} to V_{E}), the memory device 130 determines, at block 307 and based on the first set of signal and noise characteristics, an estimate (e.g., V′_{C}) of the optimized read voltage V_{O}.

For example, the memory device 130 can determine the estimate (e.g., V′_{C}) of the optimized read voltage V_{O} by computing the estimate (e.g., V′_{C}) using an extrapolation technique.

At block 309, the memory device 130 measures a second set of signal and noise characteristics of the group of memory cells (e.g., group 131 or 133) by reading the group of memory cells (e.g., group 131 or 133) at a second plurality of test voltages (e.g., V′_{A} to V′_{E}) configured according to the estimate (e.g., V′_{C}) of the optimized read voltage V_{O}.

For example, the memory device 130 can read the group of memory cells at the second plurality of test voltages V′_{A} to V′_{E} by initially ramping up to a test voltage (e.g., V′_{C}) in the second plurality of test voltages V′_{A} to V′_{E} to read the group of memory cells and then boost modulating to other test voltages (e.g., V′_{A}, V′_{B}, V′_{D}, V′_{E}) in the second plurality of test voltages V′_{A} to V′_{E} to further read the group of memory cells (e.g., group 131 or 133). In some implementations, different sub-groups of memory cells in the group (e.g., 131 or 133) are boost modulated to different test voltages (e.g., V′_{A}, V′_{B}, V′_{D}, V′_{E} respectively) for measuring in parallel. The measurements of a sub-group can be scaled to determine the measurement of the group. The memory device 130 can read the group of memory cells (e.g., group 131 or 133) via boost modulation within the range of the second plurality of test voltages V′_{A} to V′_{E} but may not be able to boost modulation to a voltage that is outside of the range V′_{A} to V′_{E} without restarting the read/calibration operation.

For example, the first plurality of test voltages V_{A} to V_{E} can be configured with a predetermined gap G between adjacent test voltages in the first plurality of test voltages V_{A} to V_{E}; the second plurality of test voltages V′_{A} to V′_{E} can be configured with the same predetermined gap G between adjacent test voltages in the second plurality of test voltages V′_{A} to V′_{E}; and a difference between one (e.g., V′_{C}) of the second plurality of test voltages V′_{A} to V′_{E} and one (e.g., V_{C}) of the first plurality of test voltages V_{A} to V_{E} is configured to be a multiple of the predetermined gap G.

At block 311, the memory device 130 computes the optimized read voltage V_{O} based at least in part on the second set of signal and noise characteristics.

Optionally, the memory device 130 computes the optimized read voltage V_{O} using at least a portion of the second set of signal and noise characteristics and at least a portion of the first set of signal and noise characteristics.

For example, the optimized read voltage V_{O} can be computed using an interpolation technique.

For example, the first set of signal and noise characteristics can include count differences D_{A} to D_{D}. The second set of signal and noise characteristics can include count differences D′_{A} to D′_{D}. The interpolation can be based on count differences D_{A} to D_{D} and D′_{A} to D′_{D}, or a portion of D_{A} to D_{D} and a portion of D′_{A} to D′_{D}.

At block 313, the memory device 130 retrieves data from the group of memory cells (e.g., group 131 or 133) using the optimized read voltage V_{O}.

For example, the memory device 130 can boost modulating to the optimized read voltage V_{O} from an applied test voltage in the second plurality of test voltages V′_{A} to V′_{E} to read the data from the group of memory cells (e.g., group 131 or 133).

If, at block 306, the memory device 130 determines that the optimized read voltage V_{O} is outside of the range (e.g., V_{A} to V_{E}), the memory device 130 computes, at block 317 and based on the first set of signal and noise characteristics, the optimized read voltage V_{O}, which can be used to retrieve, at block 313, data from the group of memory cells (e.g., group 131 or 133).

In some implementations, after measuring, at block 309, the second set of signal and noise characteristics, the memory device 130 can repeat the determination (e.g., 305 and/or 306) of whether the optimized read voltage V_{O} is within the current test voltage range (e.g., the range of the second plurality of test voltages V′_{A} to V′_{E}). If the optimized read voltage V_{O} is still outside of the current test voltage range (e.g., V′_{A} to V′_{E}), a further improved estimate of the optimized read voltage V_{O} can be determined to measure a further set of signal and noise characteristics of the group of memory cells in a way similar to blocks 307 and 309 until the optimized read voltage V_{O} is found to be within the current test voltage range. Subsequently, the optimized read voltage V_{O} can be computed based at least in part on the signal and noise characteristics measured using the test voltages within the current test voltage range.

A non-transitory computer storage medium can be used to store instructions of the firmware of a memory sub-system (e.g., 110). When the instructions are executed by the controller 115 and/or the processing device 117, the instructions cause the controller 115, the processing device 117, and/or a separate hardware module to perform the methods discussed above.

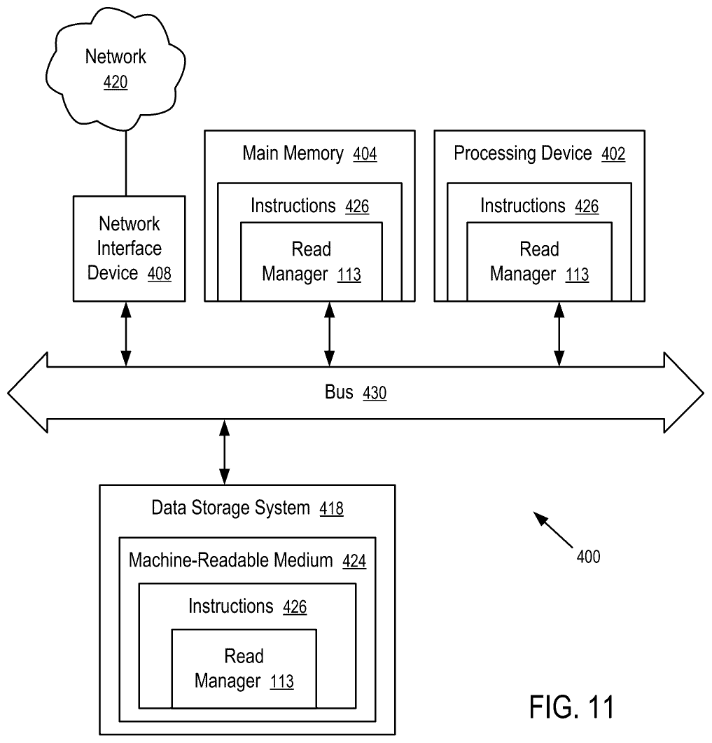

FIG. 11 illustrates an example machine of a computer system 400 within which a set of instructions, for causing the machine to perform any one or more of the methodologies discussed herein, can be executed. In some embodiments, the computer system 400 can correspond to a host system (e.g., the host system 120 of FIG. 1) that includes, is coupled to, or utilizes a memory sub-system (e.g., the memory sub-system 110 of FIG. 1) or can be used to perform the operations of a read manager 113 (e.g., to execute instructions to perform operations corresponding to the read manager 113 described with reference to FIGS. 1-9). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 400 includes a processing device 402, a main memory 404 (e.g., read-only memory (ROM), flash memory, dynamic random access memory (DRAM) such as synchronous DRAM (SDRAM) or Rambus DRAM (RDRAM), static random access memory (SRAM), etc.), and a data storage system 418, which communicate with each other via a bus 430 (which can include multiple buses).

Processing device 402 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 402 can also be one or more special-purpose processing devices such as an application specific integrated circuit (ASIC), a field programmable gate array (FPGA), a digital signal processor (DSP), network processor, or the like. The processing device 402 is configured to execute instructions 426 for performing the operations and steps discussed herein. The computer system 400 can further include a network interface device 408 to communicate over the network 420.

The data storage system 418 can include a machine-readable storage medium 424 (also known as a computer-readable medium) on which is stored one or more sets of instructions 426 or software embodying any one or more of the methodologies or functions described herein. The instructions 426 can also reside, completely or at least partially, within the main memory 404 and/or within the processing device 402 during execution thereof by the computer system 400, the main memory 404 and the processing device 402 also constituting machine-readable storage media. The machine-readable storage medium 424, data storage system 418, and/or main memory 404 can correspond to the memory sub-system 110 of FIG. 1.

In one embodiment, the instructions 426 include instructions to implement functionality corresponding to a read manager 113 (e.g., the read manager 113 described with reference to FIGS. 1-9). While the machine-readable storage medium 424 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In this description, various functions and operations are described as being performed by or caused by computer instructions to simplify description. However, those skilled in the art will recognize what is meant by such expressions is that the functions result from execution of the computer instructions by one or more controllers or processors, such as a microprocessor. Alternatively, or in combination, the functions and operations can be implemented using special purpose circuitry, with or without software instructions, such as using Application-Specific Integrated Circuit (ASIC) or Field-Programmable Gate Array (FPGA). Embodiments can be implemented using hardwired circuitry without software instructions, or in combination with software instructions. Thus, the techniques are limited neither to any specific combination of hardware circuitry and software, nor to any particular source for the instructions executed by the data processing system.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A device, comprising:
a plurality of memory cells; and
a controller configured to:
determine, based on a first set of signal and noise characteristics, whether an optimized read voltage is within a range of a first plurality of test voltages;
determine, based on the optimized read voltage being determined to be outside the range of the first plurality of test voltages, an estimate for the optimized read voltage;
measure a second set of signal and noise characteristics of the plurality of memory cells at a second plurality of test voltages configured based on the estimate for the optimized read voltage; and
compute the optimized read voltage based at least in part on the second set of signal and noise characteristics.

2. The device of claim 1, wherein the controller is further configured to retrieve data from the plurality of memory cells using the optimized read voltage.

3. The device of claim 1, wherein the controller is further configured to receive a command identifying the plurality of memory cells in the memory device.

4. The device of claim 3, wherein the controller is further configured to measure, in response to the command, the first set of signal and noise characteristics.

5. The device of claim 1, wherein the controller is further configured to compute, based on the optimized read voltage being determined to be within the range of the first plurality of test voltages, the optimized read voltage.

6. The device of claim 5, wherein the controller is further configured to retrieve the data from the plurality of memory cells using the optimized read voltage.

7. The device of claim 1, wherein the controller is further configured to apply a plurality distinct read conditions to obtain the first set of signal and noise characteristics.

8. The device of claim 1, wherein the controller is configured to compute the optimized read voltage using an interpolation based at least in part on the second set of signal and noise characteristics.

9. The device of claim 1, wherein the controller is further configured to determine the optimized read voltage by identifying a lowest count difference among count differences computed between adjacent test voltages of the first plurality of test voltages and locating the optimized read voltage within a corresponding voltage interval based on relative differences to neighboring count differences.

10. The device of claim 1, wherein the controller is further configured to obtain at least part of the first set of signal and noise characteristics by measuring subgroups of the plurality of memory cells in parallel and scaling subgroup measurements to represent the plurality of memory cells.

11. The device of claim 1, wherein the controller is further configured to predict, based at least in part on the first set or the second set of signal and noise characteristics, whether decoding of hard bit data will utilize soft bit data, and to selectively transmit the soft bit data based on the prediction.

12. The device of claim 1, wherein the controller is further configured to skip transmission of the soft bit data when a likelihood of using the soft bit data is below a threshold, and to transmit the soft bit data when the likelihood is at or above the threshold.

13. The device of claim 1, wherein the estimate for the optimized read voltage is computed by extrapolation from the first set of signal and noise characteristics when the optimized read voltage is determined to be outside the range of the first plurality of test voltages.

14. A method, comprising:
evaluating a first set of signal and noise characteristics for a plurality of memory cells to determine whether an optimized read voltage is within a range of a plurality of test voltages;
generating, when the optimized read voltage is outside the range, an estimate of the optimized read voltage based on the first set of signal and noise characteristics;
obtaining a second set of signal and noise characteristics by reading at additional test voltages selected according to the estimate;
computing the optimized read voltage based at least in part on signal and noise characteristics obtained from the readings.

15. The method of claim 14, further comprising obtaining, for the plurality of memory cells, the first set of signal and noise characteristics by reading at the plurality of test voltages.

16. The method of claim 14, further comprising retrieving data from the plurality of memory cells using the optimized read voltage.

17. The method of claim 14, further comprising constraining a change between the estimate of the optimized read voltage and a subsequent estimate to a multiple of a predetermined gap.

18. The method of claim 14, further comprising predicting whether decoding of hard bit data retrieved using the optimized read voltage requires use of soft bit data for successful decoding.

19. The method of claim 14, further comprising predicting whether hard bit data retrieved using the optimized read voltage has a likelihood of failing a test of data integrity.

20. A system, comprising:
a host system; and
a memory sub-system coupled to the host system and comprising:
a memory device having a plurality of memory cells; and
a controller configured to:
compute, based on a set of signal and noise characteristics measured for a plurality of memory cells, an optimized read voltage for the plurality of memory cells;
retrieve hard bit data from the plurality of memory cells using the optimized read voltage;
generate soft bit data by reading the plurality of memory cells at a pair of read voltages offset relative to the optimized read voltage;
predict, based on the set of signal and noise characteristics, whether decoding of the hard bit data will utilize the soft bit data.
